(19) United States
(12) Patent Application Publication
(10) Pub. No.: US 2011/0173805 A1
(43) Pub. Date: Jul. 21, 2011

(54) Hard-disk Drive Insertion

(76) Inventors: Bruno Richet, Oakland, CA (US); Fred Charles Thomas, Fort Collins, CO (US); Arthur Sandoval, San Francisco, CA (US); Daniel Francis Kennedy, San Francisco, CA (US)

(21) Appl. No.: 13/119,182

(22) PCT Filed: Oct. 30, 2008
(86) PCT No.: PCT/US2008/081703

§ 371 Date: Mar. 15, 2011

(51) Int. Cl. H05K 13/04; B25B 27/14

(52) U.S. Cl. 29/825; 29/760

(57) ABSTRACT

A hard-disk drive insertion mechanism includes carrier mechanism that moves longitudinally with the hard-disk drive as it is being inserted toward said electrical connector. The carrier mechanism includes engagement features for engaging the hard-disk drive as it is being inserted. The insertion mechanism also includes a clamping mechanism that gradually clamps the hard-disk drive with elastomeric material before it engages an electrical connector.

### BACKGROUND OF THE INVENTION

Most hard disks are provided in rectangular parallelepiped cases with screw holes that permit the cases to be mounted in a computer chassis, as is consistent with their conventional use as fixed internal devices. Thus installing a hard-disk drive (i.e., hard disk, hard drive, fixed disk drive) can involve opening a computer case, screwing (e.g., using a screw driver and screws) the hard-disk drive to the computer chassis, and closing the computer case. Open the computer case and installing the hard-disk drive typically involves the use of tools.

The burden involved in installing a hard-disk drive can be acceptable for systems that are updated infrequently. However, large computer installations, e.g., data centers, often contain arrays of hard disks that often need to be replaced, either because they are full, or because they have failed, or because they need to be replaced with higher capacity hard disks. In such a context, the down time and inconvenience associated with shutting down systems, opening cases, and screwing hard disks into place are unacceptable.

One solution to this problem is to make hard disks that are more like removable media. Also, micro hard drives have been provided in a compact flash form factor for convenient insertion and removal from compatible readers. While these removable hard disks have worked well in their intended contexts, they have not been able to take advantage of the economies of scale and market competition available to hard disks in standard form factors.

An “HDD carrier” solution involves attaching a HDD (hard-disk drive) carrier to a hard disk, which can have a standard form factor. An HDD carrier is a frame-like structure that attaches to the HDD to enable in its insertion into or removal from the system. HDD carriers are typically constructed out of metal and/or polymeric materials. In some types of computer hard-disk drive applications, the disk drives are provided in a redundant array of independent disks (RAID) for a storage subsystem. Each drive is loaded in a drive carrier and then mounted in a drawer in the subsystem. A drive carrier typically utilizes a cam mechanism in order to latch itself and the disk drive into a drawer.

Although insertion and removal are convenient and tool-less, the HDD carrier solution still requires that a carrier be attached to a hard disk. Thus some assembly is required, and that assembly typically involves tools and small parts (which can be lost). In addition, while the hard disk can be standard, the carrier and drawer must match. If a spare carrier is unavailable, replacing a hard drive can require detaching a carrier from the old drive and attaching the carrier to the new drive, before the latter can be inserted. In addition, the inserted hard disk is typically not shock mounted, so that shock to the chassis is transferred to the hard drive (subjecting it to damage) and vibrations from the hard drive are transferred to the chassis (causing a variety of problems).

### BRIEF DESCRIPTION OF THE DRAWINGS

The figures depict implementations/embodiments of the invention and not the invention itself.

FIG. 1 is an exploded view of a hard-disk drive and blind-mate insertion mechanism in accordance with an embodiment of the invention.

FIG. 2 is a bottom plan view of a base of the insertion mechanism of FIG. 1 showing the positions of springs.

FIG. 3 is a perspective view of a base of FIG. 2.

FIG. 4 is a perspective view of an assembly of the base of FIG. 3 with a PCB assembly attached.

FIG. 5 is a perspective view of the assembly of FIG. 4 with a lower carrier attached.

FIG. 6 is a perspective view of the assembly of FIG. 5 with an upper carrier attached.

FIG. 7 is a perspective view of the assembly FIG. 6 with a latch attached.

FIG. 8 is a perspective view of the assembly of FIG. 7 with a bezel attached.

FIG. 9 is a perspective view of the assembly of FIG. 8 with a hard disk partially inserted.

FIG. 10 is a perspective view of the assembly of FIG. 8 with a cover in place and a hard disk partially inserted.

FIG. 11 is a flow chart of a method in accordance with an embodiment of the invention.

FIG. 12 is a schematic diagram of an alternative insertion mechanism with a hard disk partially inserted in accordance with a second embodiment of the invention.

FIG. 13 is a schematic diagram of the alternative insertion mechanism of FIG. 11 with the hard disk more fully inserted.

FIG. 14 is a schematic diagram of the alternative insertion mechanism of FIG. 11 with the hard disk fully inserted.

FIG. 15 is a flow chart of another method in accordance with an embodiment of the invention.

### DETAILED DESCRIPTION

The present invention provides a blind-mate (no visual alignment necessary) insertion mechanism that accepts hard disks in a standard form factor, such as a standard 3.5 inch SATA drive form factor. The mechanism includes a pair of carriers that are rigidly engaged as a hard disk is inserted. As the carriers move rearward due to the insertion force, they move laterally, causing 1) elastomeric material to clamp the hard disk, and then 2) the original rigid engagement to be released. As a result of the clamping by elastomeric material, the hard disk is shock mounted, limiting the transfer of impacts and vibration between the hard disk and chassis. The invention is convenient is that no carrier, no tools, and no loose parts are required for inserting a hard disk. The invention is economical because it allows widely available and economical standard native (as manufactured) form factor hard disks to be used.

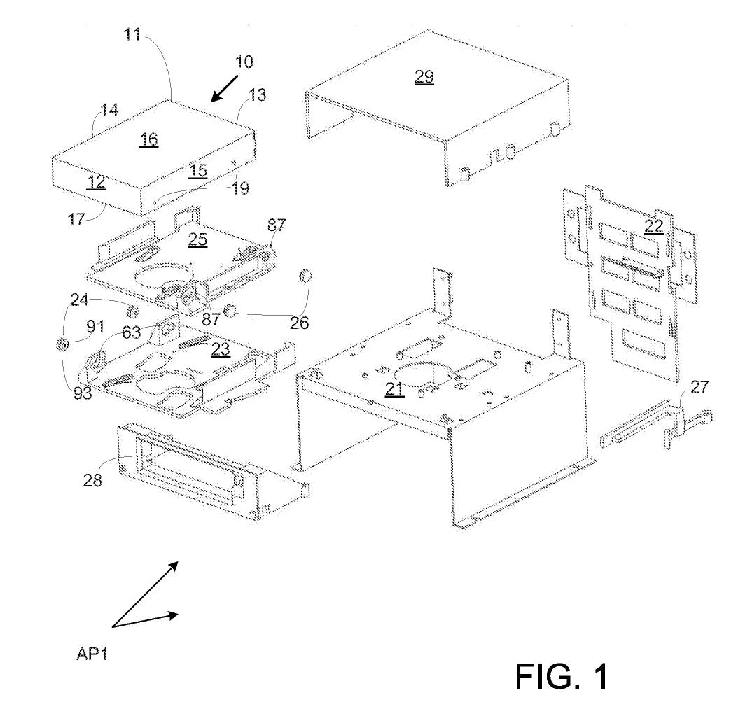

In accordance with an embodiment of the invention, an insertion mechanism AP1 for a hard disk 10 is shown in FIG. 1. As manufactured, in its native state, hard disk 10 has a standard 3.5″ SATA form factor. Hard disk 10 has a rectangular parallelpiped case 11 that encloses magnetic disk platters (not shown). Case 11 has a front wall 12, a rear wall 13, a left wall 14, a right wall 15, a top wall 16, and, a bottom wall 17. Left wall 14 and right wall 15 have screw holes 19 that are intended for mounting using screws. Rear Wall 13 has a connector for electrical and physical connection to a SATA connector.

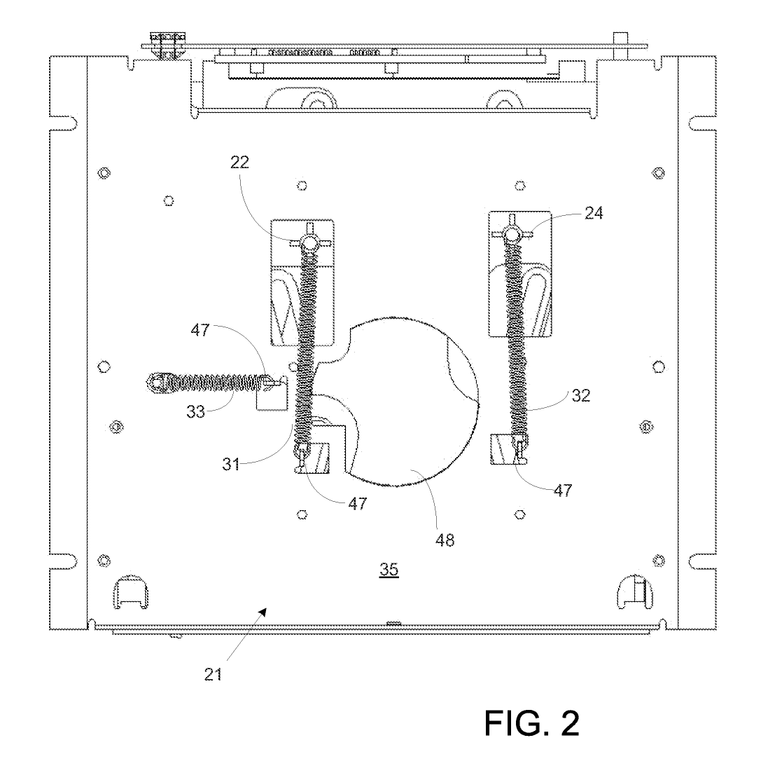

Insertion mechanism AP1 includes a base structure 21, a printed circuit board (PCB) assembly with electrical drive connection 22, a lower carrier piece 23 and associated “lower” grommet pins 24, an upper carrier piece 25 and associated “upper” grommet pins 26, a latch 27, a bezel 28, and a cover 29, all shown in FIG. 1. As shown in FIG. 2, insertion mechanism AP1 also includes three springs 31, 32, and 33 that urge components into initial positions when no hard disk is inserted or is being inserted. Springs 31 and 32 urge carriers forward, while spring 33 urges them laterally so that pins 24 move apart.

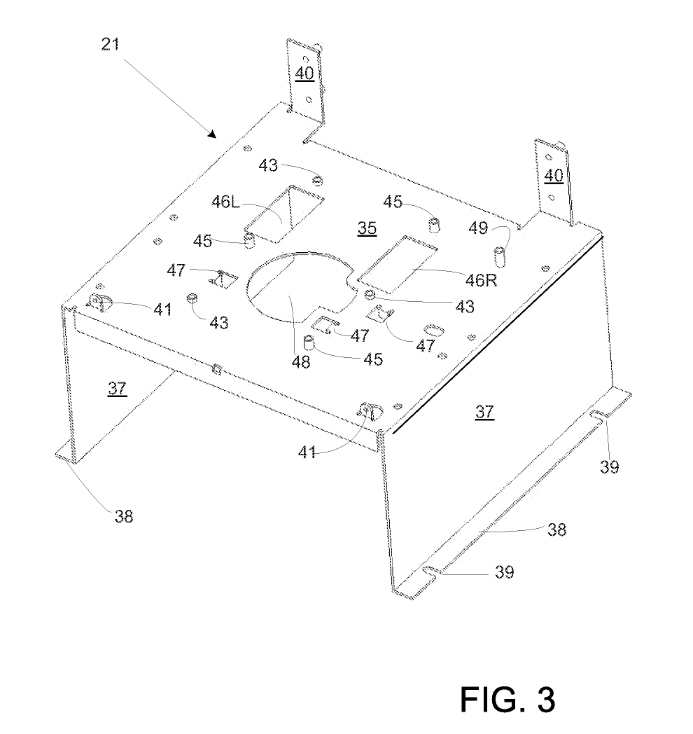

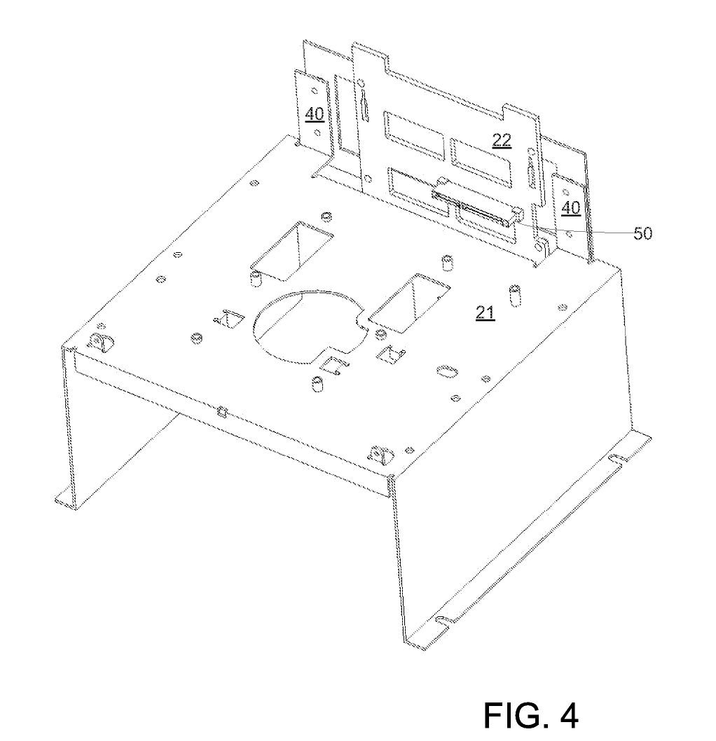

Base 21 includes a platform 35, seen from below in FIG. 2 and from above in FIG. 3. As shown in FIG. 3, base 21 also includes sidewalls 37, which serve to prop platform 35 above a chassis floor. Sidewalls 37 have flanges 38 with notches 39 for engaging screws or other mounting features at the chassis floor. Mounting brackets 40 extend upwards at the rear of base 21 to provide for attaching PCB with drive electrical interface connector assembly 22, as shown in FIG. 4. In other embodiments this PCB is replaced by sheet metal or other structural material mounted drive electrical, connectors electrically tethered to the system via an electrical cable.

As shown in FIG. 3, small upwardly extending tabs 41 at the front of platform 21 limit the forward travel of carriers 22 and 24 when they are mounted on base 21. Three short guide pins 43 contribute to controlling opposing lateral movement of lower carrier 23 during insertion and removal; three taller guide pins 45 contribute to controlling opposing lateral movement of upper carrier 25 during insertion and removal. Rectangular apertures 46L and 46R provide for physical connections between springs 31 and 32 and carriers 23 and 25. Downward extending tabs 47 engage springs 31, 32, and 33, as best seen in FIG. 2, Mushroom shaped aperture 48 is used for ventilation. A pivot pin 49 is used to hold latch 26 (FIG. 1), which can pivot relative to pin 49.

As shown in FIG. 4, PCB assembly 22 is attached to brackets 40 of base 21. PCB assembly 22 includes a SATA connector 50 to which hard disk 10 is to be physically and electrically connected once insertion is completed.

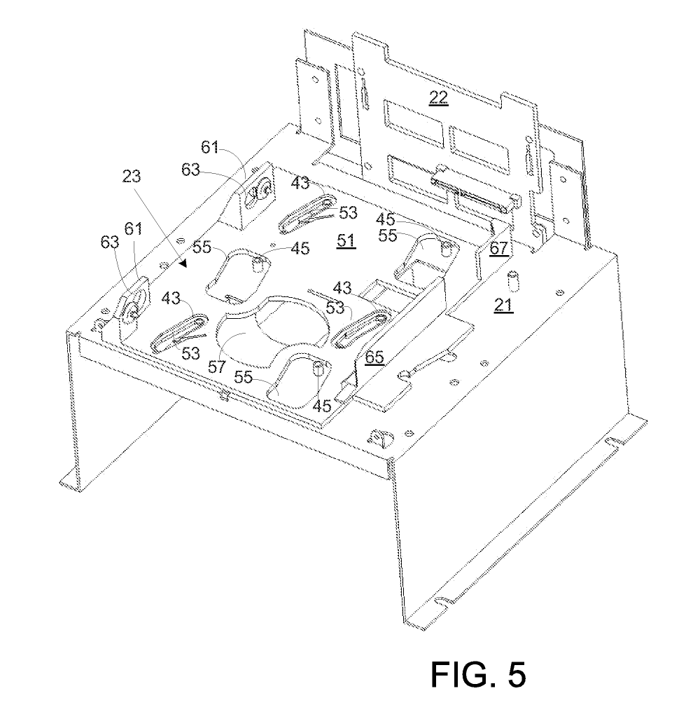

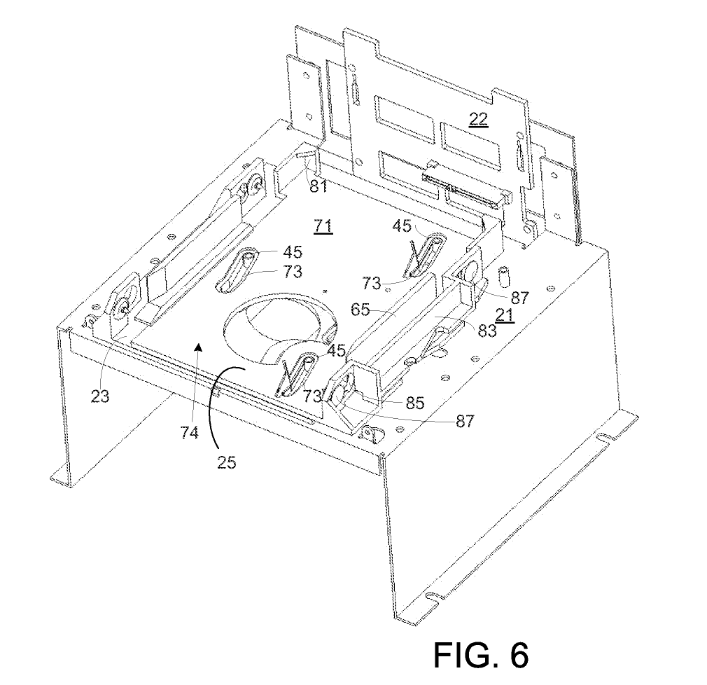

Lower carrier 23 has a planar (lower) floor 51 in which three guide slots 53 are defined, as shown in FIG. 5. These slots 53 engage short pins 43 of base 31. Slots 53 extend primarily longitudinally (front to rear), but, going front to rear and viewing from above, veer to the right. This inclination causes lower carrier 23 to move to the left as it moves rearward relative to fixed base 21. Three rhomboid apertures 55 accommodate taller guide pins 45 so that they can engage upper carrier 25 as shown in FIG. 6. A “batwing” shaped aperture 57 (FIG. 5) aligns generally with mushroom-shaped aperture 48 of base 21 to provide ventilation.

A pair of upwardly extending brackets 61 with apertures 63 is provided on the left side of lower carrier 23 to accommodate lower grommet pins 24. A partial sidewall 65 is designed to engage upper carrier 25 and latch 27 (FIG. 1), as explained further below. An L-shaped tab 67 at the right rear engages hard disk 10 as it is inserted. Once tab 67 is engaged, lower carrier 23 moves rearward relative to fixed base 21 with hard disk 10 (FIG. 1) as insertion continues. Thus, due to the action of shorter guide pins 43 and guide slots 53, lower carrier 23 moves rearward and to the left during hard disk insertion.

Upper carrier 25 has a planar (upper) floor 71 in which three guide slots 73 are defined to engage taller guide pins 45 of base 21 as shown in FIG. 6. Carriers 23 and 25 collectively define a carrier tray 74 for hard disk 10. These elongated slots 73 extend longitudinally to permit longitudinal motion of upper carrier 25 relative to fixed base 21, but veer to the left (when going from front to rear) so that upper carrier moves rightward during insertion (opposing the motion of lower carrier 23). Upper floor 71 also includes a moon-shaped aperture 77 that aligns with batwing-shaped aperture 57 (FIG. 5) of lower carrier 23 and mushroom-shaped aperture 48 (FIG. 3) of base 21 for ventilation.

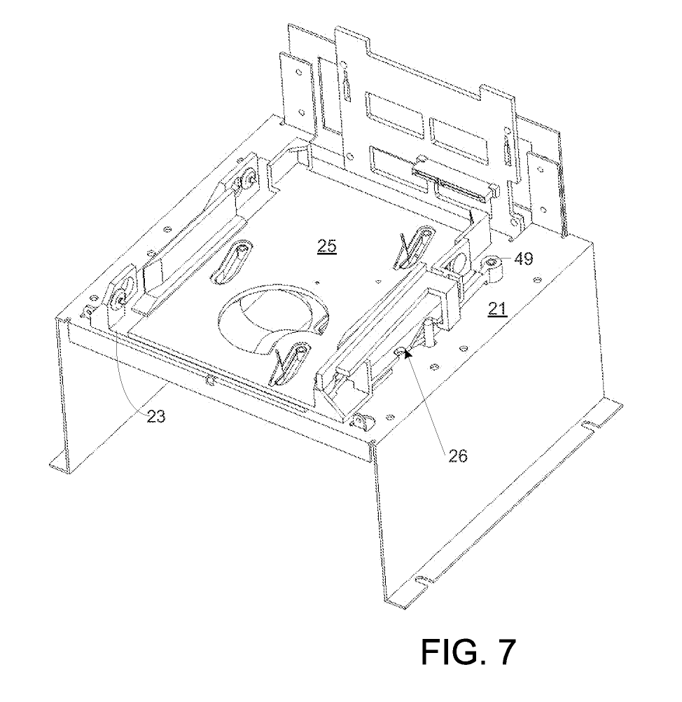

Upper carrier 25 includes a left guidewall 79 to help guide hard disk 10 upon insertion. Upper carrier 25 includes an L-shaped tab 81 for engaging hard disk 10 (FIG. 1) upon insertion. Once hard disk 10 engages tab 81 (at the same time hard disk 10 engages tab 67 of lower carrier 23), upper carrier 25 moves with hard disk 10 during further insertion. Upper carrier 25 includes a right sidewall 83 that includes apertures 85 (FIGS. 1 and 6) to accommodate upper grommet pins 26 and that engages right sidewall 65 of lower carrier 25. In addition, right sidewall 83 is shaped to engage latch 27, as shown in FIG. 7.

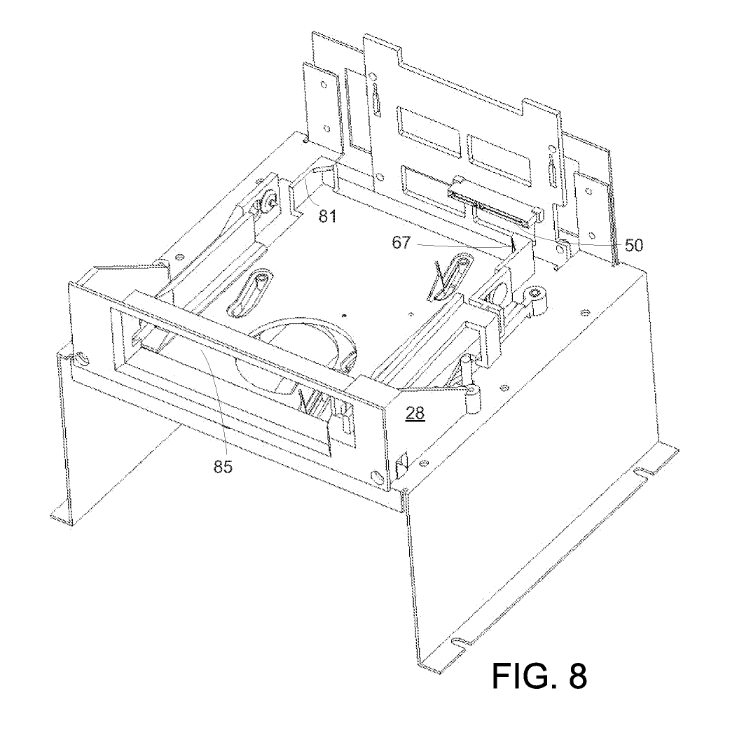

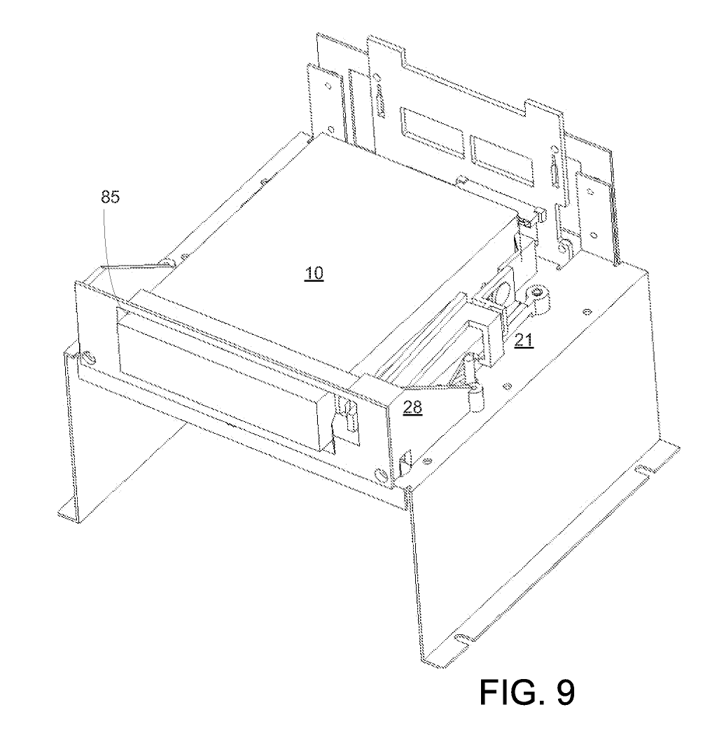

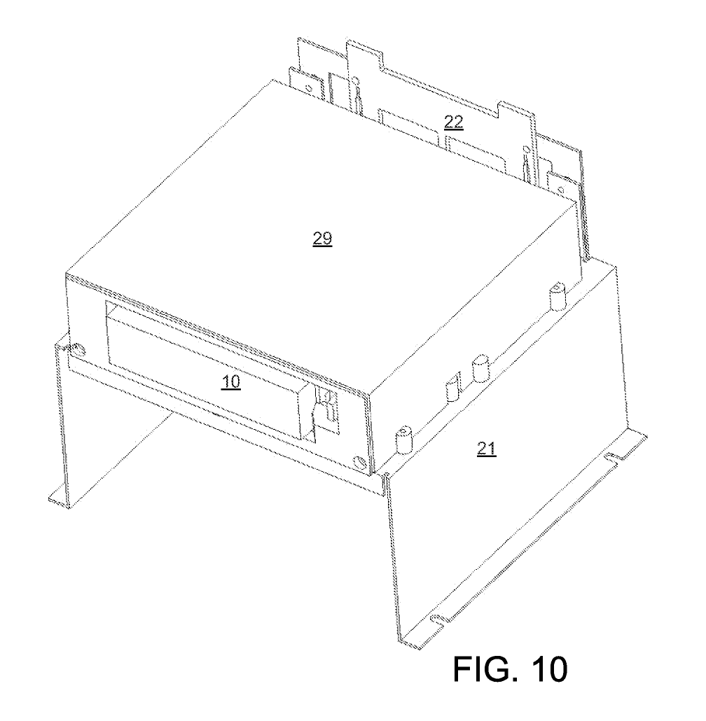

Bezel 28 is shown in place in FIG. 8. Bezel 28 includes a slot 85 though which hard disk 10 can be inserted as indicated in FIG. 9. Cover 29 is shown in place in FIG. 10.

As best seen in FIG. 1, grommet pins 24 and 26 include disk-shaped elastomeric grommets 91 with central metal pins 93. Grommet pins 24, 26 are installed in grommet slots 63 of lower carrier 23 (FIG. 5) and grommet slots 85 of upper carrier 25 (FIG. 6). When hard disk 10 is inserted, pins 93 are inserted into respective screw holes 19 of hard disk 10. Pins 93 do not securely engage hard disk 10 as screws would, but serve to guide the grommets in position against left and right walls 14 and 15 of hard disk 10, as can be inferred from FIG. 6.

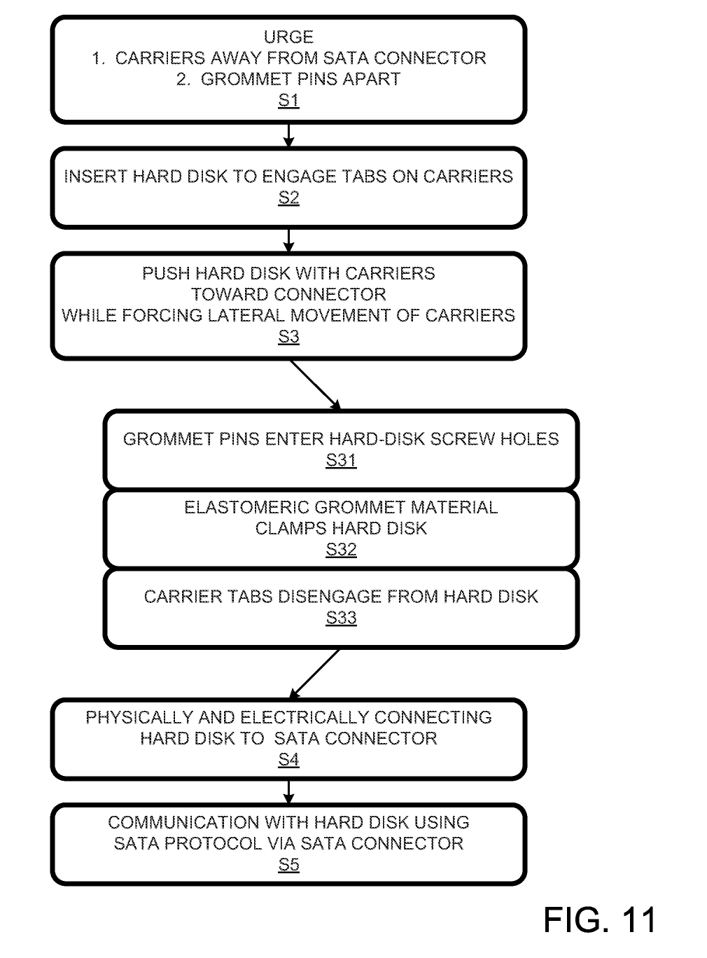

Insertion mechanism AP1 provides for the following method ME1, flow charted in FIG. 11. Step S1 represents an initial condition with carriers 23 and 25 in full, forward positions against tabs 41 (FIG. 3) under the force of springs 31 and 32 (FIG. 2). In other words, carriers 23 and 25 are their furthest distances from SATA connector 50. In addition, grommet pins 24 and 26 are at their furthest distance from each other.

At step S2, hard disk 10 is manually inserted, through slot 85 bezel 28 (FIG. 8), displacing its flap. As manual insertion continues, the rear bottom corners of hard disk 10 contact carrier tabs 67 and 81 (FIG. 8). This is a hard metal contact with little or no shock absorbing capabilities. It is used temporarily during insertion, but is relinquished by the time insertion is completed in favor of a shock-absorbing connection provided by grommet pins 24 and 26. During insertion, however, this contact causes carriers 23 and 25 to move rearward with hard disk 10 as the manual insertion force overcomes the forces of springs 31 and 33 (FIG. 2).

Step S3 involves the joint rearward motion of hard disk 10 and carriers 23 and 25 as hard disk 10 is pushed toward connector 50. Due to the action of guide pins 43 and 45 and guide slots 53 and 73 (FIGS. 5 and 6), the rearward motion forces carriers 23 and 25 to move in opposing lateral directions so that grommet pins 24 and 26 move toward each other. This lateral motion has the following effects. Effect S31 is that pins 91 (FIG. 1) enter respective screw holes 19 in sidewalls 14 and 15 of hard disk 10. Effect S32 is that grommets 93 collectively clamp hard disk 10. Effect S33 is that tabs 67 and 81 (FIG. 8) disengage from hard disk 10. Thus, a hard metal non-shock-absorbing contact is replaced with an elastomeric shock-absorbing contact. It is this latter shock-absorbing contact that remains in effect after insertion is completed and while hard disk 10 is in use.

At step S4, hard disk 10 engages connector 50 on PCB assembly 22. At this point, latch 27 (FIG. 9) engages so that hard disk 10 cannot disengage from connector 50 until latch 27 is released. Once hard disk 10 is fully inserted, it is contacted by PCB assembly 22 (via connector 50), grommet pins 24 and 26, and upper carrier floor 71 (FIG. 6). The flexibility of PCB assembly 22 and grommets 91 provides for shock-absorbing contacts that minimize the transmission of shock and vibrations. Once inserted, hard drive 10 can communicate via connector 50 using a SATA protocol, at step S5.

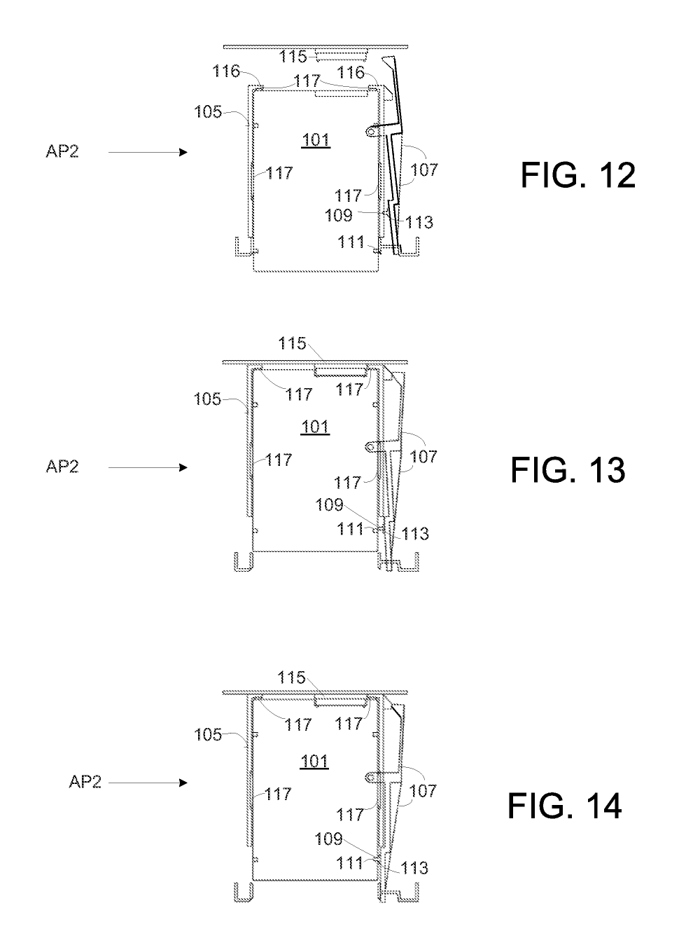

A second insertion mechanism AP2 is shown in FIGS. 12-14 with a hard disk 101 successively partially inserted, more fully inserted, and fully inserted. Insertion mechanism AP2 includes a carrier tray 105 that is not split in the manner carrier 74 of the first insertion mechanism AP1. Instead, a latch mechanism 107 provides for lateral movement of an attached unthreaded pin 109 that is inserted into a threaded mounting hole 111 of hard disk 101 in the process of insertion, as indicated by a comparison of FIGS. 13 and 14. Pin 109 is attached to latch 107 using a press-fitted elastomeric grommet 113 to provide shock and vibration, isolation at this connection; latch 107, pin 109 and grommet 113 serve to clamp hard disk 101 to tray 105. Additional elastomeric pads 115 provide further isolation from shock and vibration.

Like insertion mechanism AP1, insertion mechanism AP2 provides for a use model like that associated with floppy disks and flash media. The user simply takes a standard hard disk and inserts it into bay. The difference, of course, is that there is no drive mechanism in the bay; the drive mechanism is built into the hard disk enclosure. However, from the user's perspective, inserting is preferable to installing.

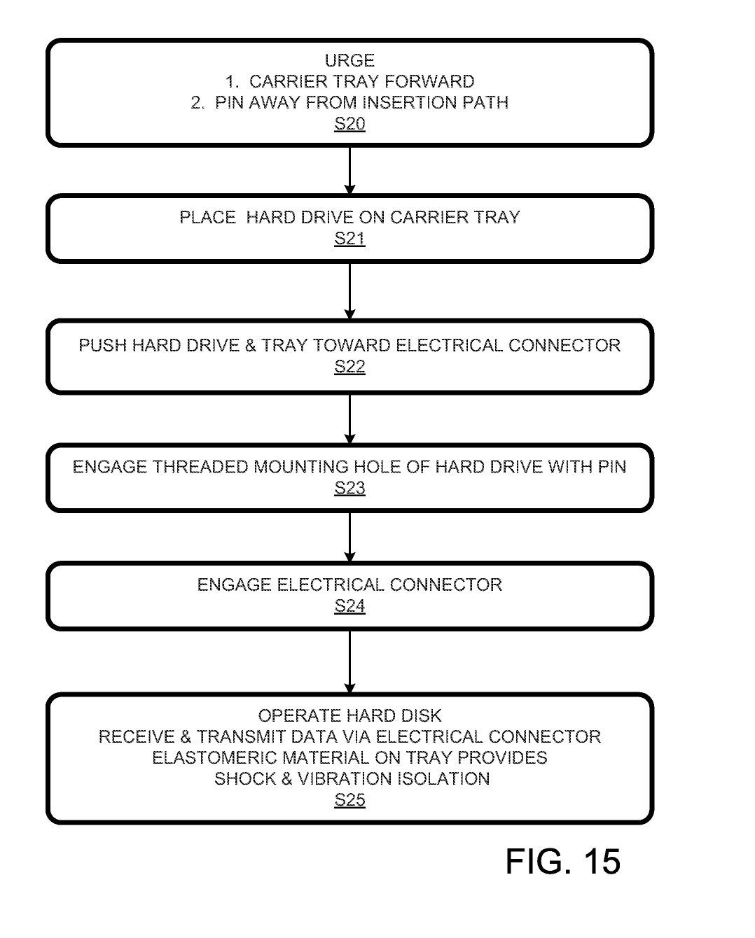

Thus, system AP2 provide for a method ME2 as flow-charted in FIG. 15. Initial conditions at step 20 include tray 105 being urged forward and that is urged forward and a latch 107 pivoted so that pin 109 is away from the insertion path. At step S21, a user places a standard form-factor hard drive onto slideable tray so that it contacts tabs 116 or other engagement features. At this point, the hard drive is not attached to the tray; it is simply held in place by gravity. At step S22, the user forces the hard drive, and thus the tray, toward an electrical connector 117. At step S23, while the tray and hard drive are moving rearward, a pin moves laterally to engage a threaded mounting hole in the hard drive and fix its position relative to the tray. With the hard drive position so fixed, further rearward motion of the tray causes the hard disk to engage electrical connector 117 at step S24. At step S25, the hard disk is operated so as to receive and transmit data via connector 117, while elastomeric material on tray isolates shock and vibrations.

In accordance with the foregoing description, the invention provides for carrier-less and tool-less insertion of a native (as manufactured) form factor hard disk, while providing for a shock-absorbing support for the inserted hard disk. The invention provides for many variations upon the illustrated embodiment. Dimensions can be changed to accommodate different form factors, e.g., 5.25″ or 2.5″ hard disks, as well as other hard disk protocols such as SCSI and IDE. Also, not all embodiments required grommet pins to be inserted in screw holes. The invention can also permit the insertion of devices other than hard disks, including drives for removable media (e.g., a DVD ROM drive).

The foregoing description, for purposes of explanation, has been described with reference to specific embodiments. However, the illustrative discussions are not intended to be exhaustive or to limit the invention to the precise forms disclosed. Many modifications and variations are possible in view of the disclosed teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A hard-disk insertion mechanism for longitudinally inserting a hard disk so that it mechanically and electrically mates with an electrical connector, said mechanism comprising:
a carrier mechanism that moves longitudinally with said hard disk as it is being inserted toward said electrical, connector, said carrier mechanism including engagement features for engaging said hard disk as it is being inserted; and
a clamping mechanism that gradually contacts said device with elastomeric material as it is being inserted so that said device is clamped using said elastomeric material before said hard disk mates with said electrical connector.

2. A hard-disk insertion mechanism as recited in claim 1 wherein said clamping mechanism includes a pin that engages a mounting hole in said hard disk as said hard disk is being inserted.

3. A hard-disk insertion mechanism as recited in claim 2 where said pin is unthreaded and said hole is threaded.

4. A hard-disk insertion mechanism as recited in claim 3 wherein other than at said pin and said electrical connector, said hard disk only contacts elastomeric material on said carrier means when mated to said electrical connector.

5. A hard-disk insertion mechanism as recited in claim 4 further comprising a pivotable latch, said pin being attached to said latch with a press-fitted elastomeric grommet.

6. A hard-disk insertion mechanism as recited in claim 1 wherein said carrier means includes a pair of carriers that move laterally during insertion so as to clamp said hard disk.

7. A hard-disk insertion mechanism as recited in claim 6 wherein said carriers include tabs that engage and then disengage said hard disk during insertion.

8. A hard-disk mechanism as recited in claim 7 further comprising springs that urge said carriers away from said electrical connector.

9. A hard-disk insertion method comprising:
placing a hard disk on a carrier of an insertion mechanism;
pushing said hard disk so that said hard disk and said carrier move longitudinally toward a connector;
laterally engaging a mounting hole of said disk drive with a pin so as to clamp said hard drive to said carrier; and
push said hard disk so that it engages an electrical connector.

10. A method as recited in claim 9 wherein said mounting hole is threaded and said pin is not threaded.

11. A method as recited in claim 9 wherein said laterally engaging involves pivoting a latch to which said pin is attached via a press-fitted elastomeric grommet.

12. A method as recited in claim 9 further comprising urging said carrier forward before placing said hard disk on said carrier.

13. A method as recited in claim 9 wherein said placing said hard disk on said carrier involves placing said hard disk in contact with elastomeric material.

14. A method as recited in claim 9 wherein said carrier includes two carrier pieces that move laterally relative to each other so as to clamp said hard disk as it is pushed toward said connector.

15. A method as recited in claim 9 wherein said pin is attached to one of said carrier pieces.
